(19) United States
(12) Patent Application Publication
(10) Pub. No.: US 2026/0349014 A1
(43) Pub. Date: Nov. 5, 2026

(54) SUB-FEMTO FARAD CAPACITANCE MEASUREMENT CIRCUIT

(71) Applicant: University of Washington, Seattle, WA (US)

(72) Inventors: Jae-Hyun CHUNG, Seattle, WA (US); Tianyi LI, Seattle, WA (US); Vigneshwar SAKTHIVELPATHI, Seattle, WA (US); Zhongjie QIAN, Seattle, WA (US)

(73) Assignee: University of Washington, Seattle, WA (US)

(21) Appl. No.: 19/130,887

(22) PCT Filed: Nov. 16, 2023
(86) PCT No.: PCT/US2023/080110

§ 371 Date: May 16, 2025

Related U.S. Application Data
(60) Provisional application No. 63/384,318, filed on Nov. 18, 2022.

(51) Int. Cl. G01R 27/26; H03K 17/955

(52) U.S. Cl. CPC G01R 27/2605; H03K 17/955; H03K 2217/960715; H03K 2217/960735

(57) ABSTRACT

A measurement circuit, including a timer oscillator, where the timer oscillator includes a common collector voltage (V_{cc}) supply pin, a trigger pin, a threshold pin, and an output pin configured to produce a square pulse wave of frequency. The measurement circuit further includes a first resistor coupled to the V_{cc} supply pin, a second resistor coupled to the first circuit, and a feedback capacitor coupled to the output pin and the trigger pin, where the measurement circuit is configured to sense a change in capacitance below 1 pF.

### CROSS-REFERENCE TO RELATED APPLICATION

This application claims the benefit of U.S. Provisional Patent Application No. 63/384,318, filed Nov. 18, 2022, the disclosure of which is hereby incorporated by reference in its entirety.

### BACKGROUND

Current capacitance to digital converters with the ability to measure capacity changes below 1 pF conventionally utilize switched capacitor delta-sigma CDCs and an LC tank resonance circuit, such as FDC1004 and FDC2214 from Texas Instruments and AD7745 from Analog devices. Sub-femto capacitance measurement circuits are not always as sensitive as may be desired, most having a resolution of 1 fF.

Accordingly, improvements to current capacitance to digital converters are needed.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, disclosed herein is a measurement circuit, including a timer oscillator. The timer oscillator includes a common collector voltage (V_{cc}) supply pin, a trigger pin, a threshold pin, and an output pin configured to produce a square pulse wave of frequency. The measurement circuit further includes a first resistor coupled to the V_{cc} supply pin, a second resistor coupled to the first circuit, and a feedback capacitor coupled to the output pin and the trigger pin, where the measurement circuit is configured to sense a change in capacitance below 1 pF.

In some embodiments, the square pulse wave is a continuous square pulse wave of frequency.

The measurement circuit of claim 1 or claim 2, wherein the V_{cc} supplies a voltage of about 4.5 V to about 18 V.

In some embodiments, wherein the measurement circuit is further configured to detect a change in capacitance of at least 0.01 fF.

In some embodiments, a ratio between a first resistance of the first resistor and a second resistance of the second resistor ranges from about 0.05 to about 50. In some embodiments, a first resistance of the first resistor ranges from 1K-1M ohms. In some embodiments, a second resistance of the second resistor ranges from 1K-1M ohms. In some embodiments, the wave of frequency ranges from about 70 kHz and 450 kHz. In some embodiments, the first resistor and the second resistor are arranged in series.

In some embodiments, the timer oscillator further comprises a discharge, wherein the discharge is between the first resistor and the second resistor. In some embodiments, the timer oscillator is a 555 circuit.

In another aspect, disclosed herein is a system including a microcontroller, the measurement circuit as described herein, and a capacitance sensor coupled to the measurement circuit.

In some embodiments, the measurement circuit is integrated into the microcontroller. In some embodiments, the measurement circuit is coupled to the microcontroller with a multiplexer of the microcontroller. In some embodiments, the microcontroller is communicatively coupled to an external device. In some embodiments, the microcontroller is coupled to a power source. In some embodiments, the microcontroller is coupled to a communication module. In some embodiments, the microcontroller is configured to convert the continuous square pulse wave of frequency into a capacitance measurement.

In some embodiments, measurement circuit is a first measurement circuit, and the system further comprises a second measurement circuit. In some embodiments, the capacitance sensor is a first capacitance sensor, and the system further comprises a second capacitance sensor coupled to the second measurement circuit.

In some embodiments, the system further includes a third measurement circuit coupled to the first capacitance sensor, and a fourth measurement circuit coupled to the second capacitance sensor.

In some embodiments, the system is configured to operate the first measurement circuit, the second measurement circuit, the third measurement circuit, and the fourth measurement circuit simultaneously. In some embodiments, the system is configured to operate the first measurement circuit, the second measurement circuit, the third measurement circuit, and the fourth measurement circuit sequentially.

In some embodiments, the system further includes a third measurement circuit coupled to a third capacitance sensor, and a fourth measurement circuit coupled to a fourth capacitance sensor.

In some embodiments, the capacitance sensor is a carbon nanotube capacitance sensor.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a schematic example capacitive measurement circuit, in accordance with the present technology;

FIG. 2 is an example capacitance measurement system, in accordance with the present technology;

FIGS. 3-6 are graphs showing data from an example measurement circuit in operation; in accordance with the present technology;

FIG. 7 is an example system including a measurement circuit coupled to a single capacitance sensor, in accordance with the present technology;

FIG. 8 is an example system including two measurement circuits where each measurement circuit is coupled to a respective capacitance sensor in accordance with the present technology;

FIG. 9 is another example system 900 including four measurement circuits 910A, 910B, 910C, 910D coupled to two capacitance sensors 905A, 905B, in accordance with the present technology; and

FIG. 10 is an example implementation of systems integrated into a flooring, in accordance with the present technology.

### DETAILED DESCRIPTION

While illustrative embodiments have been illustrated and described, it will be appreciated that various changes can be made therein without departing from the spirit and scope of the invention.

Described herein is a measurement circuit configured to measure capacitance changes of at least 0.01 fF. In some embodiments, the measurement circuit includes a timer oscillator. The timer oscillator may include a common collector voltage (V_{cc}) supply pin, a trigger pin, a threshold pin, and an output pin configured to produce a square pulse wave of frequency. The measurement circuit may further include a first resistor coupled to the V_{cc} supply pin, a second resistor coupled to the first circuit, and a feedback capacitor coupled to the output pin and the trigger pin. In this manner, the measurement circuit is configured to sense a change in capacitance below 1 pF. Also described herein are example systems incorporating the measurement circuit, or multiple measurement circuits. In some embodiments, the measurement circuit(s) are coupled to one or more capacitance sensors. Also described herein, in some embodiments one or more systems as described herein are used in flooring, window, security, or other applications.

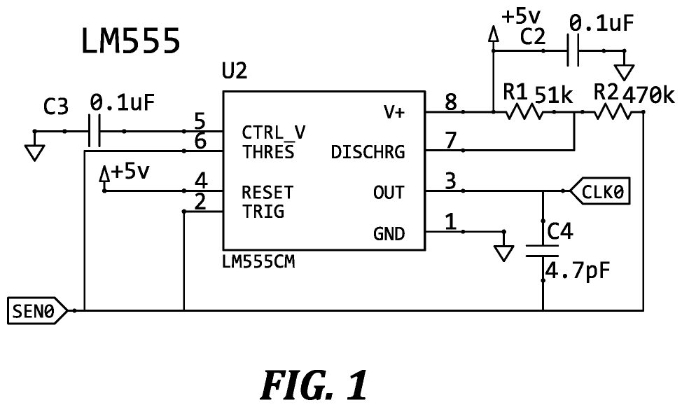

Turning now to the FIGURES, FIG. 1 is a schematic example capacitive measurement circuit, in accordance with the present technology. In some embodiments, the measurement circuit includes a LM555 oscillator. As shown in FIG. 1, the measurement circuit may include a supplied voltage V_{cc} (pin 8 in FIG. 1). In some embodiments, the supplied voltage may be about 4.5 to 18V. In some embodiments, the measurement circuit further includes a pull-up capacitor (pin 8 in FIG. 1). In some embodiments, the pull-up capacitor is installed between an output 3 and a trigger 2. In some embodiments, the measurement circuit further includes a timer oscillator. In some embodiments, the timer oscillator is an LM555 oscillator. In some embodiments, the LM555 oscillator is in an astable mode.

In some embodiments, the measurement circuit is configured to output a continuous square pulse-wave of varying frequencies having a high duty cycle. As described herein, a high duty cycle may be a duty cycle of about 80-99%. The output is illustrated in FIG. 1 as CLKO. In some embodiments, the measurement circuit is configured to sense a change in capacitance below 1 pF. In some embodiments, the measurement circuit is further configured to detect a change in capacitance of at least 0.01 fF (10 aF). In some embodiments, the resolution depends on the clock frequency of the measurement circuit. Below 10 aF may be limited by thermal noise.

As described herein, the measurement circuit outputs square pulses. The equation to convert the measured frequency into capacitance may be:

c=(frq−470750)/(−7892) (Equation 1)
wherein C is the capacitance, and frq is the frequency. It should be understood that this is merely a representative equation. In some embodiments, the equation changes based on the combination of the first and second resistors.

In some embodiments, the accuracy of the sensor is inversely proportional to the sampling rate. For example, at 50 sps, the RMS error of the measurement circuit would be 0.3 fF.

In some embodiments, the measurement circuit includes a timer oscillator. In some embodiments, the timer oscillator includes a common collector voltage (V_{cc}) supply pin, a trigger pin, a threshold pin, and an output pin configured to produce a continuous square pulse wave of frequency. The measurement circuit may further include a first resistor coupled to the V_{cc} supply pin, a second resistor coupled to the first circuit, and a feedback capacitor coupled to the output pin and the trigger pin.

In some embodiments, a ratio between a first resistance of the first resistor and a second resistance of the second resistor ranges from about 0.05 to about 50. In some embodiments, a first resistance of the first resistor ranges from 1K-1M ohms. In some embodiments, a second resistance of the second resistor ranges from 1K-1M ohms. In some embodiments, the range of frequencies is between about 70 kHz and 450 kHz. In some embodiments, the first resistor and the second resistor are arranged in series.

In some embodiments, the measurement circuit is coupled with a capacitance sensor (SENO in FIG. 1). The capacitive sensor may be connected to pin 6 (the threshold) of the timer oscillator. In some embodiments, the capacitance sensor is a rectangular electrode capacitance sensor. In some embodiments, the capacitance sensor is fabricated with carbon nanotubes. In some embodiments, the measurement circuit is coupled with a plurality of capacitance sensors. In some embodiments, the measurement circuit is coupled with additional measurement circuits, each coupled with a single capacitance sensor.

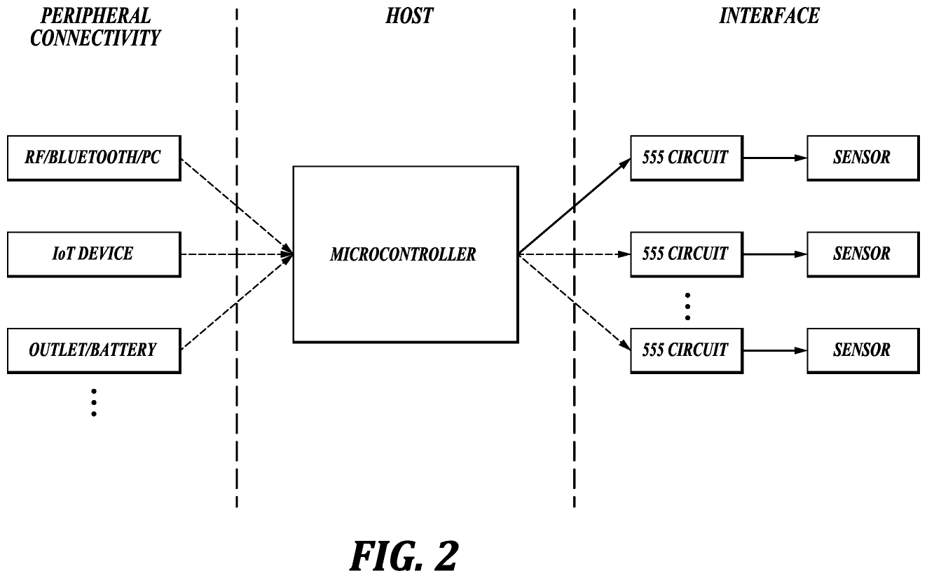

FIG. 2 is an example capacitance measurement system, in accordance with the present technology. In another aspect, a capacitance measurement system, including a microcontroller, the measurement circuit as described herein; and a capacitance sensor coupled to the measurement circuit is disclosed.

In some embodiments, the measurement circuit is integrated into the microcontroller, but in other embodiments, the measurement circuit is coupled to the microcontroller with a multiplexer of the microcontroller.

In some embodiments, the microcontroller is communicatively coupled to an external device. In some embodiments, the external device may be an Internet of Things (IoT) device. In some embodiments, the microcontroller is coupled to a power source, such as an outlet, a battery, or the like.

In some embodiments, the microcontroller is coupled to a communication module. In some embodiments, the communication module may be configured to connect the microcontroller to a device using a personal area network (such as BLUETOOTH®), radiofrequency identification (RFID), or the like.

In some embodiments, the microcontroller is configured to convert a square pulse wave of frequency into a capacitance measurement. In some embodiments, the square pulse wave of frequency is a continuous square pulse wave of frequency. In some embodiments, the measurement circuit is a first measurement circuit, and the system further comprises a second measurement circuit. While two measurement circuits are illustrated in FIG. 2, it should be understood that any number of measurement circuits coupled to any number of capacitance sensors may be utilized. In some embodiments, the capacitance sensor is a first capacitance sensor, and the system further comprises a second capacitance sensor coupled to the second measurement circuit. In some embodiments, the system further includes a third measurement circuit coupled to a third capacitance sensor, and a fourth measurement circuit coupled to a fourth capacitance sensor. In some embodiments, the capacitance sensor is a carbon nanotube capacitance sensor.

### Examples

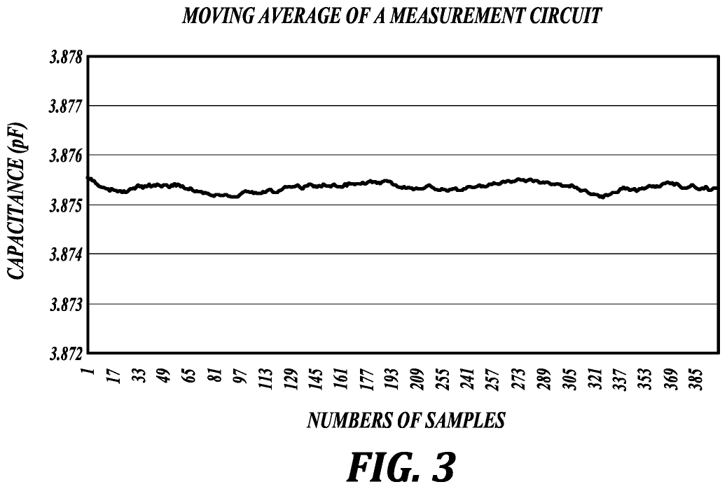

FIGS. 3-6 are graphs showing data from an example measurement circuit in operation; in accordance with the present technology. The following is the data of the measurement circuit including a capacitive sensor.

FIG. 3 shows a graph of the moving average of the measurement circuit. On the horizontal axis is the numbers of samples. On the vertical axis is the capacitance in pF. As shown, the measurement circuit is capable of measuring changes of smaller than 1 fF. The capacitance value has a noise smaller than 1 fF. With signal processing, the accuracy can be increased to 10 aF.

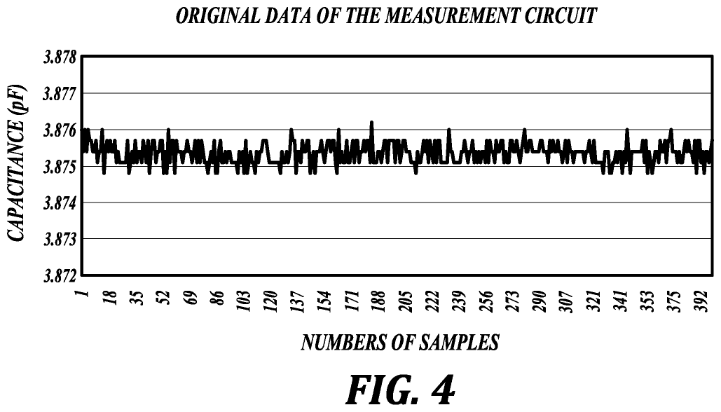

FIG. 4 shows a graph the moving average of the measurement circuit without signal processing. FIG. 4 shows the original data of the measurement circuit without signal processing. On the horizontal axis is the number of samples. On the vertical axis is the capacitance in pF. When the original data is processed, the results of FIG. 3 are achieved.

An example measurement circuit was fabricated. In some embodiments, the measurement circuit includes a 555 circuit in combination with microcontroller that works as low as 0.01 fF (10 aF). Using a clock frequency greater than 10 kHz, frequency modulation is conducted to measure capacitance. The conversion equation may be:

c=(frq−470750)/(−7892) (Equation 2)

wherein C is the capacitance and frq is the frequency. It should be understood that this equation is merely representative. The conversion equation may be based on the combination of first and second resistors.

Based on the capacitive measurement, the microcontroller can measure proximity, liquid, objects, and/or pressure. The microcontroller can also be used to control other devices and switches. Universal serial bus (USB) serial communication, inter-integrated circuit (I2C) communication, radio-frequency (RF) communication, personal area network (PAN) (such as BLUETOOTH®) communication, or the like may be utilized to connect the microcontroller to any number of other devices.

Based on the application of a large voltage (such as 4.5 V to 18 V), the proximity distance that the sensor can measure is enhanced to 1500 mm. For example, when 12V is applied, the proximity distance based on the 555 circuit is 1500 mm. In some embodiments, the proximity distance increases as the supplied voltage increases because the electric field magnitude increases. In some embodiments, the supplied voltage ranges from about 4.5 V to about 18 V.

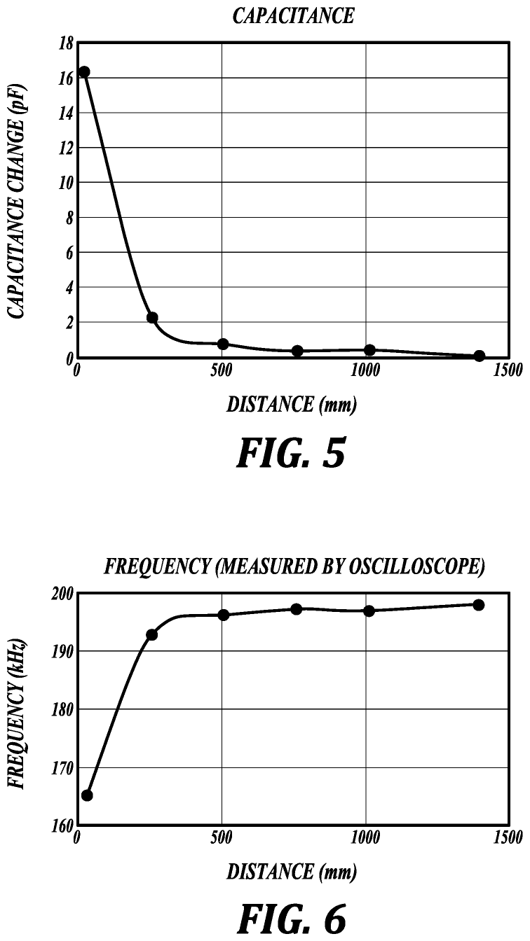

FIG. 5 is a graph of the capacitance measurement at various distances. On the horizontal axis is the distance in millimeters. On the vertical axis is the capacitance change in pF. As shown, the capacitance changes of an object, in this case a human hand, was able to be measured up to 1500 mm.

FIG. 6 is a graph of the frequency measurement at various distances. The frequency ranges from 165 kHz to 198 kHz, as shown in FIG. 6. On the horizontal axis is the distance in millimeters. On the vertical axis is the frequency in kilohertz. The frequency was also able to be measured up to 1500 mm. The frequency of the LM555 timer may be nominally 315 kHz and give a delta between 315 kHz and 285 kHz when modified by proximity, or for example, a human hand. In some embodiments, the operating temperature range of the capacitance sensor in an automotive application is-20 to +120 deg F.

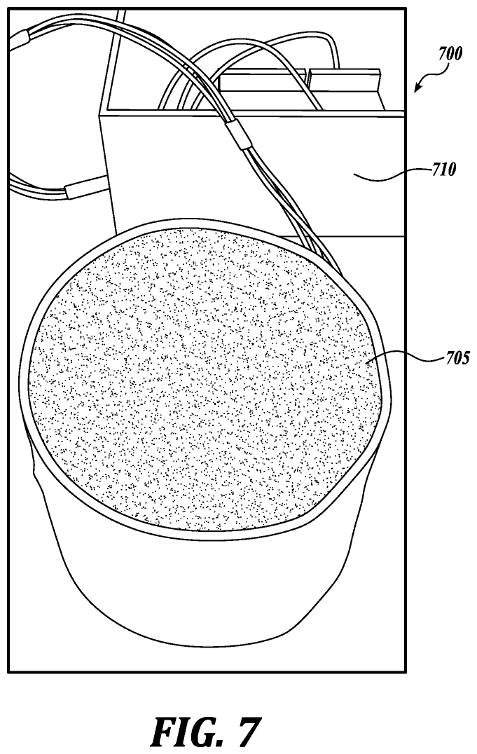

FIG. 7 is an example system 700 including a measurement circuit 710 coupled to a single capacitance sensor 705, in accordance with the present technology. In some embodiments, the system 700 includes a single measurement circuit 710 coupled to a single capacitance sensor 705. In some embodiments, the measurement circuit 710 is the measurement circuit illustrated and described in FIG. 1. In some embodiments, the system 700 is the system illustrated and described in FIG. 2.

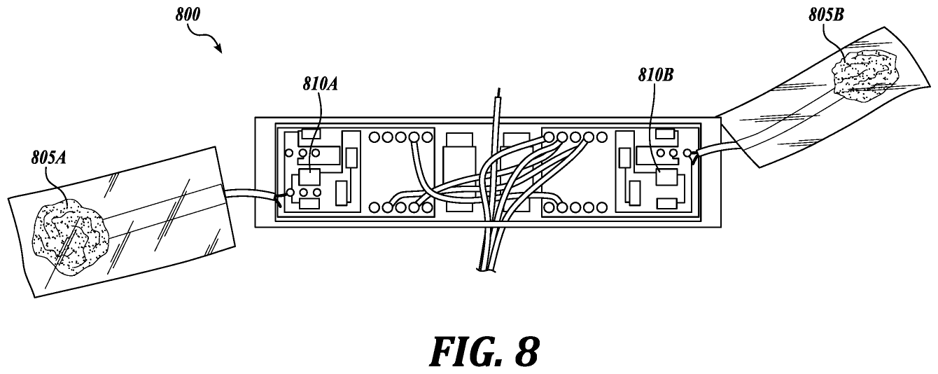

FIG. 8 is an example system 800 including two measurement circuits 810A, 810B, where each measurement circuit 810A, 810B is coupled to a respective capacitance sensor 805A, 805B, in accordance with the present technology. In some embodiments, the system 800 includes any number of measurement circuits 810A, 810B, each coupled to a respective capacitance sensor 805A, 805B. Each capacitance sensor 805A, 805B may be operated simultaneously or sequentially to avoid frequency interference. In some embodiments, there may be a single microcontroller (as shown in FIG. 2) coupled to both measurement circuits 810A, 810B, but in other embodiments, each measurement circuit 810A, 810B may be coupled to a respective microcontroller.

In some embodiments, the measurement circuit operates as a frequency to voltage convertor.

The transfer function of the frequency convertor may give 50 mV change for a 1 pF change in the “Sensor Puck”. The PIC processor measures the frequency of the sensor and outputs a voltage using the DAC with a transfer function of:

$$\frac{5 V}{100 kHz} = \frac{0.1 V}{20 kHz} \qquad ( Equation 3 )$$

where V is voltage in volts and kHz is kilohertz of frequency.

TABLE 1
Example frequency to voltage conversions

| Frequency | Voltage | |
|---|---|---|
| 500 kHz | 2.5 | V |
| 250 kHz | 1.25 | V |
| 100 kHz | .5 | V |

### Table 1: Example Frequency to Voltage Conversions

The transfer function chosen is decided by the software program and the accuracy is chosen by the software by way of the sample rate configuration. The microprocessor may count the sensor signal at a 48 MHz, 32 MHz or depending on the microprocessor configuration. The accuracy of the frequency counter is governed by the sample clock period or:

$$\frac{1}{48 e6} = 20.8 nS \qquad ( Equation 4 )$$

Microprocessor power consumption may also be governed by the clock rate. For example, an operating frequency of 16 MHz or 1/3 the max rate will consume less power but give a less accurate count. This trade-off is controlled by the microprocessor configuration and can be chosen regardless of the hardware design. In some embodiments, the system is able to sample and report the frequency at least 1000 times per second.

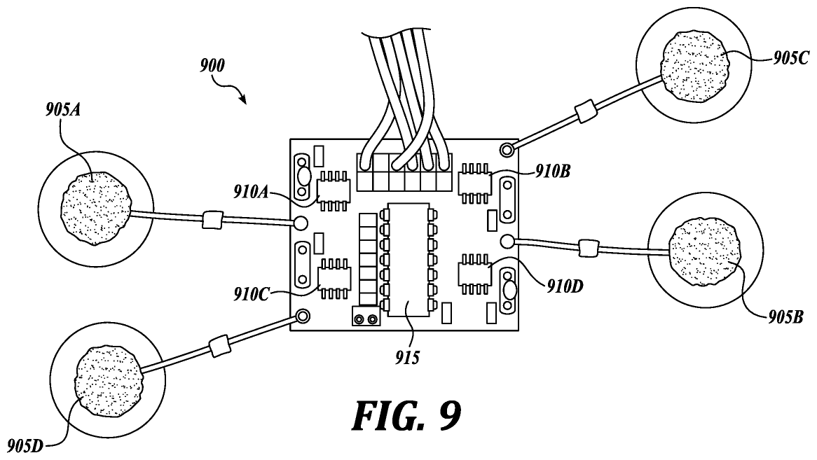

FIG. 9 is another example system 900 including four measurement circuits 910A, 910B, 910C, 910D coupled to four capacitance sensors 905A, 905B, 905C, 905D in accordance with the present technology. In some embodiments, each measurement circuit 910A, 910B, 910C, 910D is a measurement circuit as described and illustrated in FIG. 1. In some embodiments, the system 900 is an example of the system described and illustrated in FIG. 2. In some embodiments, four measurement circuits 910A, 910B, 910C, 910D are located on a single chip. In some embodiments, four sensors 905A, 905B, 905C, 905D are coupled with the chip. In this manner, the four measurement circuits 910A, 910B, 910C, 910D can be controlled with a single microprocessor (or microcontroller). The four measurement circuits 910A, 910B, 910C, 910D may be operated by a single peripheral interface controller (PIC) 915. In some embodiments, the four measurement circuits 910A, 910B, 910C, 910D are controlled simultaneously or sequentially. In some embodiments, controlling the four measurement circuits 910A, 910B, 910C, 910D in this manner avoids or reduces frequency interference.

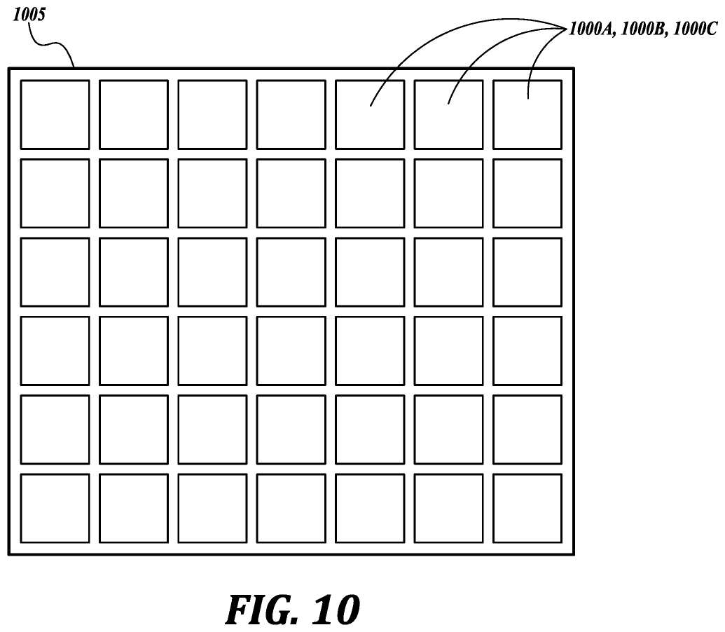

FIG. 10 is an example implementation of systems 1000A, 1000B, 1000C integrated into a flooring 1005, in accordance with the present technology. In some embodiments, the systems 1000A, 1000B, 1000C are the systems 700, 800, 900, or otherwise described herein. In some embodiments, the systems 1000A, 1000B, 1000C are arranged in an array on, behind, or inside of a flooring 1005. In some embodiments, the flooring 1005 may be hard flooring, such as wood, vinyl, or the like.

In operation, the systems 1000A, 1000B, 1000C may detect presence of an object, person, or otherwise in close proximity with the floor. In this manner, the systems 1000A, 1000B, 1000C, may be used to determine a number of people who have entered or left a space, a location of one or more objects, persons, animals, etc. in a space, or the like.

The present application may reference quantities and numbers. Unless specifically stated, such quantities and numbers are not to be considered restrictive, but representative of the possible quantities or numbers associated with the present application. Also, in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A, B, and C,” for example, means (A), (B), (C), (A and B), (A and C), (B and C), or (A, B, and C), including all further possible permutations when greater than three elements are listed.

Embodiments disclosed herein may utilize circuitry in order to implement technologies and methodologies described herein, operatively connect two or more components, generate information, determine operation conditions, control an appliance, device, or method, and/or the like. Circuitry of any type can be used. In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), or the like, or any combinations thereof, and can include discrete digital or analog circuit elements or electronics, or combinations thereof.

In an embodiment, circuitry includes one or more ASICs having a plurality of predefined logic components. In an embodiment, circuitry includes one or more FPGA having a plurality of programmable logic components. In an embodiment, circuitry includes hardware circuit implementations (e.g., implementations in analog circuitry, implementations in digital circuitry, and the like, and combinations thereof). In an embodiment, circuitry includes combinations of circuits and computer program products having software or firmware instructions stored on one or more computer readable memories that work together to cause a device to perform one or more methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like. In an embodiment, circuitry includes a baseband integrated circuit or applications processor integrated circuit or a similar integrated circuit in a server, a cellular network device, other network device, or other computing device. In an embodiment, circuitry includes one or more remotely located components. In an embodiment, remotely located components are operatively connected via wireless communication. In an embodiment, remotely located components are operatively connected via one or more receivers, transmitters, transceivers, or the like.

An embodiment includes one or more data stores that, for example, store instructions or data. Non-limiting examples of one or more data stores include volatile memory (e.g., Random Access memory (RAM), Dynamic Random Access memory (DRAM), or the like), non-volatile memory (e.g., Read-Only memory (ROM), Electrically Erasable Programmable Read-Only memory (EEPROM), Compact Disc Read-Only memory (CD-ROM), or the like), persistent memory, or the like. Further non-limiting examples of one or more data stores include Erasable Programmable Read-Only memory (EPROM), flash memory, or the like. The one or more data stores can be connected to, for example, one or more computing devices by one or more instructions, data, or power buses.

In an embodiment, circuitry includes one or more computer-readable media drives, interface sockets, Universal Serial Bus (USB) ports, memory card slots, or the like, and one or more input/output components such as, for example, a graphical user interface, a display, a keyboard, a keypad, a trackball, a joystick, a touch-screen, a mouse, a switch, a dial, or the like, and any other peripheral device. In an embodiment, circuitry includes one or more user input/output components that are operatively connected to at least one computing device to control (electrical, electromechanical, software-implemented, firmware-implemented, or other control, or combinations thereof) one or more aspects of the embodiment.

In an embodiment, circuitry includes a computer-readable media drive or memory slot configured to accept signal-bearing medium (e.g., computer-readable memory media, computer-readable recording media, or the like). In an embodiment, a program for causing a system to execute any of the disclosed methods can be stored on, for example, a computer-readable recording medium (CRMM), a signal-bearing medium, or the like. Non-limiting examples of signal-bearing media include a recordable type medium such as any form of flash memory, magnetic tape, floppy disk, a hard disk drive, a Compact Disc (CD), a Digital Video Disk (DVD), Blu-Ray Disc, a digital tape, a computer memory, or the like, as well as transmission type medium such as a digital and/or an analog communication medium (e.g., a fiber optic cable, a waveguide, a wired communications link, a wireless communication link (e.g., transmitter, receiver, transceiver, transmission logic, reception logic, etc.). Further non-limiting examples of signal-bearing media include, but are not limited to, DVD-ROM, DVD-RAM, DVD+RW, DVD-RW, DVD-R, DVD+R, CD-ROM, Super Audio CD, CD-R, CD+R, CD+RW, CD-RW, Video Compact Discs, Super Video Discs, flash memory, magnetic tape, magneto-optic disk, MINIDISC, non-volatile memory card, EEPROM, optical disk, optical storage, RAM, ROM, system memory, web server, or the like.

The detailed description set forth above in connection with the appended drawings, where like numerals reference like elements, are intended as a description of various embodiments of the present disclosure and are not intended to represent the only embodiments. Each embodiment described in this disclosure is provided merely as an example or illustration and should not be construed as preferred or advantageous over other embodiments. The illustrative examples provided herein are not intended to be exhaustive or to limit the disclosure to the precise forms disclosed. Similarly, any steps described herein may be interchangeable with other steps, or combinations of steps, in order to achieve the same or substantially similar result. Generally, the embodiments disclosed herein are non-limiting, and the inventors contemplate that other embodiments within the scope of this disclosure may include structures and functionalities from more than one specific embodiment shown in the figures and described in the specification.

In the foregoing description, specific details are set forth to provide a thorough understanding of exemplary embodiments of the present disclosure. It will be apparent to one skilled in the art, however, that the embodiments disclosed herein may be practiced without embodying all the specific details. In some instances, well-known process steps have not been described in detail in order not to unnecessarily obscure various aspects of the present disclosure. Further, it will be appreciated that embodiments of the present disclosure may employ any combination of features described herein.

The present application may include references to directions, such as “vertical,” “horizontal,” “front,” “rear,” “left,” “right,” “top,” and “bottom,” etc. These references, and other similar references in the present application, are intended to assist in helping describe and understand the particular embodiment (such as when the embodiment is positioned for use) and are not intended to limit the present disclosure to these directions or locations.

The present application may also reference quantities and numbers. Unless specifically stated, such quantities and numbers are not to be considered restrictive, but exemplary of the possible quantities or numbers associated with the present application. Also, in this regard, the present application may use the term “plurality” to reference a quantity or number. In this regard, the term “plurality” is meant to be any number that is more than one, for example, two, three, four, five, etc. The term “about,” “approximately,” etc., means plus or minus 5% of the stated value. The term “based upon” means “based at least partially upon.′

The principles, representative embodiments, and modes of operation of the present disclosure have been described in the foregoing description. However, aspects of the present disclosure, which are intended to be protected, are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure as claimed.

While illustrative embodiments have been illustrated and described, it will be appreciated that various changes can be made therein without departing from the spirit and scope of the invention.

1. A measurement circuit, comprising:
a timer oscillator comprising:
a common collector voltage (V_{cc}) supply pin,
a trigger pin,
a threshold pin, and
an output pin configured to produce a square pulse wave of frequency;
a first resistor coupled to the V_{cc} supply pin;
a second resistor coupled to the first resistor; and
a feedback capacitor coupled to the output pin and the trigger pin,
wherein the measurement circuit is configured to sense a change in capacitance below 1 pF.

2. The measurement circuit of claim 1, wherein the square pulse wave is a continuous square pulse wave of frequency.

3. The measurement circuit of claim 1, wherein the V_{cc} supplies a voltage of about 4.5 V to about 18 V.

4. The measurement circuit of claim 1, wherein the measurement circuit is further configured to detect a change in capacitance of at least 0.01 fF.

5. The measurement circuit of claim 1, wherein a ratio between a first resistance of the first resistor and a second resistance of the second resistor ranges from about 0.05 to about 50.

6. The measurement circuit of claim 1, wherein a first resistance of the first resistor ranges from 1K-1M ohms, a second resistance of the second resistor ranges from 1K-1M ohms, or both.

7. (canceled)

8. The measurement circuit of claim 1, wherein the wave of frequency ranges from about 70 kHz and 450 kHz.

9. The measurement circuit of claim 1, wherein the first resistor and the second resistor are arranged in series.

10. The measurement circuit of claim 1, wherein the timer oscillator further comprises a discharge, wherein the discharge is between the first resistor and the second resistor.

11. The measurement circuit of claim 1, wherein the timer oscillator is a 555 circuit.

12-22. (canceled)

23. A capacitance measurement system, comprising:
a microcontroller;
the measurement circuit according to claim 1; and
a capacitance sensor coupled to the measurement circuit.

24. The system of claim 23, wherein the measurement circuit is integrated into the microcontroller or the measurement circuit is coupled to the microcontroller with a multiplexer of the microcontroller, or both.

25. (canceled)

26. The system of claim 23, wherein the microcontroller is communicatively coupled to an external device, a power source, a communication module, or a combination thereof.

27. (canceled)

28. (canceled)

29. The system of claim 23, wherein the microcontroller is configured to convert the continuous square pulse wave of frequency into a capacitance measurement.

30. The system of claim 23, wherein the measurement circuit is a first measurement circuit, and the system further comprises a second measurement circuit.

31. The system of claim 30, wherein the capacitance sensor is a first capacitance sensor, and the system further comprises a second capacitance sensor coupled to the second measurement circuit.

32. The system of claim 31, wherein the system further comprises:
a third measurement circuit coupled to the first capacitance sensor; and
a fourth measurement circuit coupled to the second capacitance sensor.

33. The system of claim 32, wherein the system is configured to operate the first measurement circuit, the second measurement circuit, the third measurement circuit, and the fourth measurement circuit simultaneously or sequentially.

34. (canceled)

35. The system of claim 30, wherein the system further comprises:
a third measurement circuit coupled to a third capacitance sensor; and
a fourth measurement circuit coupled to a fourth capacitance sensor.

36. The system of claim 23, wherein the capacitance sensor is a carbon nanotube capacitance sensor.
